(19) United States
(12) Patent Application Publication
(10) Pub. No.: US 2026/0344450 A1
(43) Pub. Date: Oct. 29, 2026

(54) SEMICONDUCTOR STRUCTURE AND MANUFACTURING METHOD THEREOF

(71) Applicant: Shangya Technology CO., LTD., Taipei (TW)

(72) Inventors: Pin-Pin Huang, Taipei (TW); Chun-Ko Chen, Taipei (TW)

(21) Appl. No.: 19/293,346

(22) Filed: Aug. 7, 2025

(30) Foreign Application Priority Data
Apr. 23, 2025 (TW) 114115417

(51) Int. Cl. H10W 46/00

(52) U.S. Cl. CPC H10W 46/00; H10W 46/301

(57) ABSTRACT

A semiconductor structure and a manufacturing method thereof are provided. The semiconductor structure comprises a transparent substrate, an epitaxial structure, and a distributed Bragg reflector structure. The epitaxial structure is disposed on a side surface of the transparent substrate, and the distributed Bragg reflector structure is disposed on a back side of the transparent substrate opposite to the epitaxial structure. Visible light can substantially pass through the epitaxial structure, the transparent substrate, and the distributed Bragg reflector structure in sequence, while other light outside the visible light is substantially reflected back into the transparent substrate by the distributed Bragg reflector structure.

### CROSS-REFERENCES TO RELATED APPLICATIONS

This application claims the benefit of priority to Taiwanese Patent Application No. 114115417 filed on Apr. 23, 2025, which is hereby incorporated by reference in its entirety.

### BACKGROUND OF THE INVENTION

### Field of the Invention

This invention relates to a semiconductor structure and a manufacturing method thereof, and in particular to a semiconductor structure and a manufacturing method thereof for improving optical alignment calibration.

### Descriptions of the Related Art

Optical alignment calibration technology is a critical issue in semiconductor manufacturing processes, particularly during the photolithography stage, where it ensures precise alignment of patterns on a wafer to achieve accurate multilayer structure overlay. This technology involves using optical systems to detect alignment marks and adjusting the position of the wafer or reticle based on the positions of these marks, thereby ensuring nanometer-scale precision.

Optical alignment calibration techniques applied to transparent substrates (e.g., silicon carbide substrates, gallium nitride substrates, or other transparent materials) differ from those used in traditional silicon-based processes. This is primarily due to the physical properties of transparent substrates, such as optical transparency, refractive index, and thickness uniformity, which pose unique challenges for the design and implementation of optical alignment calibration systems. Specifically, conventional techniques employ metal reflectors disposed on one side of the transparent substrate to significantly enhance the intensity and contrast of the alignment mark reflection signals.

However, the use of metal reflectors is associated with two primary issues. The first issue is the limited high-temperature tolerance of metal reflectors, which cannot withstand high temperatures encountered in manufacturing processes (e.g., up to 800 °C). As a result, metal reflectors may deform or degrade in performance during high-temperature processes, affecting the stability of process outcomes. Additionally, metal reflectors exhibit high reflectivity in the visible light region, which interferes with alignment marks and impacts subsequent exposure lithography processes, leading to ineffective alignment calibration.

### SUMMARY OF THE INVENTION

The primary objective of this invention is to provide an innovative semiconductor structure and a manufacturing method thereof, incorporating a dual-band distributed Bragg reflector structure in a transparent substrate for optical alignment calibration during manufacturing processes. The structure achieves high reflectivity for light at 436 nanometers (nm) and 940 nm, while providing high average transmittance for visible light in the 500 to 750 nm range. This enables edge-finding alignment for transparent substrates, enhances alignment mark calibration in the photolithography processes, and improves the accuracy and intensity of exposure wavelengths in photolithography. Furthermore, the dual-band distributed Bragg reflector structure of this invention exhibits high-temperature resistance, capable of withstanding process temperatures exceeding 800 °C, ensuring the stability of the reflector structure during subsequent high-temperature film deposition processes, thereby improving the precision and efficiency of alignment calibration.

To achieve the above objective, this invention provides a semiconductor structure comprising a transparent substrate, an epitaxial structure, and a distributed Bragg reflector structure. The epitaxial structure is disposed on a side surface of the transparent substrate, and the distributed Bragg reflector structure is disposed on a back side of the transparent substrate opposite to the epitaxial structure. Visible light can substantially pass through the epitaxial structure, the transparent substrate, and the distributed Bragg reflector structure in sequence, while other light outside the visible spectrum is substantially reflected back into the transparent substrate by the distributed Bragg reflector structure.

In one embodiment of the semiconductor structure of this invention, the distributed Bragg reflector structure comprises a first symmetric film stack having a plurality of pairs of a first oxide film and a second oxide film alternately stacked, wherein the refractive index of the first oxide film is greater than the refractive index of the second oxide film.

In one embodiment of the semiconductor structure of this invention, the thicknesses of the first oxide films and the second oxide films in the first symmetric film stack exhibit a first front-to-rear symmetric relationship.

In one embodiment of the semiconductor structure of this invention, the distributed Bragg reflector structure further comprises a second symmetric film stack having a plurality of pairs of the first oxide film and the second oxide film alternately stacked, wherein the thicknesses of the first oxide films and the second oxide films in the second symmetric film stack are greater than those in the first symmetric film stack.

In one embodiment of the semiconductor structure of this invention, the thicknesses of the first oxide films and the second oxide films in the second symmetric film stack exhibit a second front-to-rear symmetric relationship.

In one embodiment of the semiconductor structure of this invention, the refractive indices of the first oxide film and the second oxide film range from 1.4 to 3.0.

In one embodiment of the semiconductor structure of this invention, the first oxide film and the second oxide film are selected from the group consisting of silicon dioxide (SiO₂), titanium dioxide (TiO₂), tantalum pentoxide (Ta₂O₅), niobium pentoxide (Nb₂O₅), aluminum oxide (Al₂O₃), and zirconium dioxide (ZrO₂).

In one embodiment of the semiconductor structure of this invention, the thicknesses of the first oxide films and the second oxide films in the first symmetric film stack range from 20 to 60 nanometers (nm).

In one embodiment of the semiconductor structure of this invention, the thicknesses of the first oxide films and the second oxide films in the second symmetric film stack range from 50 to 220 nanometers (nm).

In one embodiment of the semiconductor structure of this invention, the total thickness of the distributed Bragg reflector structure ranges from 800 nanometers (nm) to 3 micrometers (μm).

In one embodiment of the semiconductor structure of this invention, the other light comprises dual-band light at 436 nanometers (nm) and 940 nanometers (nm).

To achieve the above objective, this invention provides a semiconductor structure comprising a transparent substrate and a distributed Bragg reflector structure. The distributed Bragg reflector structure is disposed on a back side of the transparent substrate. The distributed Bragg reflector structure comprises a first symmetric film stack and a second symmetric film stack, the first symmetric film stack having a plurality of pairs of a low-refractive-index oxide film and a high-refractive-index oxide film alternately stacked, and the second symmetric film stack having a plurality of pairs of the low-refractive-index oxide film and the high-refractive-index oxide film alternately stacked. The thicknesses of the low-refractive-index oxide films and the high-refractive-index oxide films in the second symmetric film stack are greater than those in the first symmetric film stack. Visible light can substantially pass through the transparent substrate and the distributed Bragg reflector structure in sequence, while other light outside the visible spectrum is substantially reflected back into the transparent substrate by the distributed Bragg reflector structure.

In one embodiment of the semiconductor structure of this invention, the thicknesses of the low-refractive-index oxide films and the high-refractive-index oxide films in the first symmetric film stack exhibit a first front-to-rear symmetric relationship, and the thicknesses of the low-refractive-index oxide films and the high-refractive-index oxide films in the second symmetric film stack exhibit a second front-to-rear symmetric relationship.

In one embodiment of the semiconductor structure of this invention, the refractive indices of the low-refractive-index oxide film and the high-refractive-index oxide film range from 1.4 to 3.0.

In one embodiment of the semiconductor structure of this invention, the low-refractive-index oxide film and the high-refractive-index oxide film are selected from the group consisting of silicon dioxide (SiO₂), titanium dioxide (TiO₂), tantalum pentoxide (Ta₂O₅), niobium pentoxide (Nb₂O₅), aluminum oxide (Al₂O₃), and zirconium dioxide (ZrO₂).

In one embodiment of the semiconductor structure of this invention, the thicknesses of the low-refractive-index oxide films and the high-refractive-index oxide films in the first symmetric film stack range from 20 to 60 nanometers (nm).

In one embodiment of the semiconductor structure of this invention, the thicknesses of the low-refractive-index oxide films and the high-refractive-index oxide films in the second symmetric film stack range from 50 to 220 nanometers (nm).

In one embodiment of the semiconductor structure of this invention, the total thickness of the distributed Bragg reflector structure ranges from 800 nanometers (nm) to 3 micrometers (μm).

In one embodiment of the semiconductor structure of this invention, the other light comprises dual-band light at 436 nanometers (nm) and 940 nanometers (nm).

To achieve the above objective, this invention provides a manufacturing method for a semiconductor structure, comprising the following steps. First, provide a transparent substrate. Second, form a distributed Bragg reflector structure disposed on a back side of the transparent substrate. The distributed Bragg reflector structure comprises a first symmetric film stack having a plurality of pairs of a low-refractive-index oxide film and a high-refractive-index oxide film alternately stacked, and a second symmetric film stack having a plurality of pairs of the low-refractive-index oxide film and the high-refractive-index oxide film alternately stacked, wherein the thicknesses of the oxide films in the second symmetric film stack are greater than those in the first symmetric film stack, such that visible light can substantially pass through the transparent substrate and the distributed Bragg reflector structure in sequence, while other light outside the visible spectrum is substantially reflected back into the transparent substrate by the distributed Bragg reflector structure.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a schematic diagram illustrating a semiconductor structure in one embodiment of this invention;

FIG. 2 is a schematic diagram illustrating the front-to-rear symmetric relationships of two symmetric film stacks in a distributed Bragg reflector structure in one embodiment of this invention;

FIG. 3 is a schematic diagram illustrating the design spectrum of a dual-band distributed Bragg reflector in one embodiment of this invention; and

FIG. 4 is a schematic diagram illustrating the process steps of a semiconductor structure in one embodiment of this invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

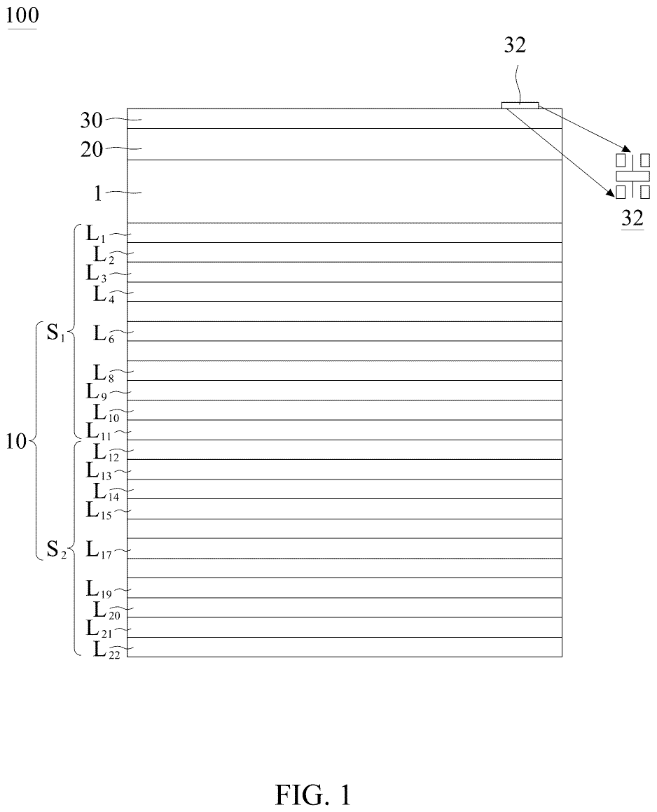

Please refer to FIG. 1, which illustrates a schematic diagram of a semiconductor structure in one embodiment of this invention. In this embodiment, the semiconductor structure 100 comprises a transparent substrate 1, a distributed Bragg reflector (DBR) structure 10, and an epitaxial structure 20. The transparent substrate 1 may be, but is not limited to, a sapphire substrate, a silicon carbide substrate, or a gallium nitride substrate. To address the challenges associated with optical alignment calibration for transparent substrates in conventional technologies, this invention specifically forms a distributed Bragg reflector structure 10 on the exposed back side of the transparent substrate 1 prior to the epitaxial process for device fabrication, for use in optical alignment calibration during subsequent patterning processes of the epitaxial structure on the transparent substrate, as detailed below.

Next, an epitaxial process is performed on the transparent substrate 1 to form an epitaxial structure 20. Subsequently, a photoresist layer 30 and an alignment mark 32 on the photoresist layer 30 are formed. The photoresist layer 30 is the so-called zero layer, used to establish a reference coordinate system for the entire wafer and to provide the alignment mark 32. A top-view enlarged diagram of the alignment mark is shown in the partial enlarged region indicated by the reference line in FIG. 1. It should be noted that the epitaxial structure 20 can be grown with different epitaxial films based on the design requirements of the actual device application, thereby forming various types of devices, such as, but not limited to, Schottky diodes or high electron mobility transistors (HEMTs) on third-generation semiconductor transparent substrates. Since this invention does not focus on the internal design of the epitaxial structure, the epitaxial structure is represented simply as an epitaxial structure 20, and detailed technical specifics of the device structure are omitted. Those skilled in the art can readily apply the optical alignment calibration technology of this invention to the epitaxial processes of various devices to achieve high-precision and stable alignment calibration.

Please continue referring to FIG. 1, where the distributed Bragg reflector structure 10, disposed on the back side of the transparent substrate 1 opposite to the epitaxial structure 20, will be described in detail. As shown, in a preferred embodiment, the distributed Bragg reflector structure 10 of this invention is a dual-band distributed Bragg reflector, allowing visible light in the wavelength range of 500 to 750 nanometers (nm) to substantially pass through the epitaxial structure 20, the transparent substrate 1, and the distributed Bragg reflector structure 10 in sequence. On the other hand, light outside the visible spectrum, such as, but not limited to, ultraviolet light at 436 nm and/or infrared light at 940 nm, is substantially reflected back into the transparent substrate 1 by the distributed Bragg reflector structure 10.

In detail, in a preferred embodiment, the distributed Bragg reflector structure 10 of this invention comprises two sets of symmetric optical film stacks, including a first symmetric film stack S₁ and a second symmetric film stack S₂. The first symmetric film stack S₁ comprises a plurality of pairs of alternately stacked optical dielectric films, each pair comprising a first oxide film and a second oxide film. Similarly, the second symmetric film stack S₂ also comprises a plurality of pairs of alternately stacked first oxide films and second oxide films. Specifically, the first oxide film is a high-refractive-index oxide film, while the second oxide film is a low-refractive-index oxide film. For example, the first oxide film may be, but is not limited to, titanium dioxide (TiO₂) with a refractive index of approximately 2.2 to 2.7. The second oxide film may be, but is not limited to, silicon dioxide (SiO₂) with a refractive index of approximately 1.4 to 1.5. In practice, the first oxide film and the second oxide film may be selected from oxide dielectric materials with refractive indices ranging from 1.4 to 3.0, such as silicon dioxide (SiO₂), titanium dioxide (TiO₂), tantalum pentoxide (Ta₂O₅), niobium pentoxide (Nb₂O₅), aluminum oxide (Al₂O₃), or zirconium dioxide (ZrO₂), choosing two high- and low-refractive-index oxide dielectric materials for alternate stacking.

Taking the first oxide film as titanium dioxide (TiO₂) and the second oxide film as silicon dioxide (SiO₂) as an example, the dual-band distributed Bragg reflector structure 10 of this invention comprises a first symmetric film stack S₁ and a second symmetric film stack S₂, each having 11 layers of alternately stacked high- and low-refractive-index oxide films, though not limited thereto. For instance, the distributed Bragg reflector structure 10 of this invention may comprise two or more symmetric film stacks, and the number of pairs or layers of alternately stacked optical films in each symmetric film stack may be increased or decreased based on practical applications.

Taking the distributed Bragg reflector structure 10 comprising two film stacks, the first symmetric film stack S₁ and the second symmetric film stack S₂, each with 11 layers of oxide films, as an example, as shown in Table 1 and FIG. 1, the first symmetric film stack S₁ comprises the 1st oxide film L₁, the 2nd oxide film L₂, the 3rd oxide film L₃, . . . , and the 11th oxide film L₁, while the second symmetric film stack S₂ comprises the 12th oxide film L₁₂, . . . , the 20th oxide film L₂₀, the 21st oxide film L₂₁, and the 22nd oxide film L₂₂, with each layer of oxide films alternately stacked using titanium dioxide (TiO₂) and silicon dioxide (SiO₂). Since both of these oxide dielectric materials are high-temperature-resistant, with titanium dioxide (TiO₂) having a melting point of approximately 1843 °C and silicon dioxide (SiO₂) having a melting point of approximately 1713 °C, the distributed Bragg reflector structure 10 of this invention can withstand process temperatures exceeding 800 °C.

TABLE 1

| | First symmetric film stack S₁ | | | | | Second symmetric film stack S₂ | | | | |
|---|---|---|---|---|---|---|---|---|---|---|
| Lay- | L₁ | L₂ | L₃ | . . . | L₁₁ | L₁₂ | . . . | L₂₀ | L₂₁ | L₂₂ |
| ers | | | | | | | | | | |
| Ox- | TiO₂ | SiO₂ | TiO₂ | | TiO₂ | SiO₂ | | SiO₂ | TiO₂ | SiO₂ |
| ide | | | | | | | | | | |
| Film | | | | | | | | | | |

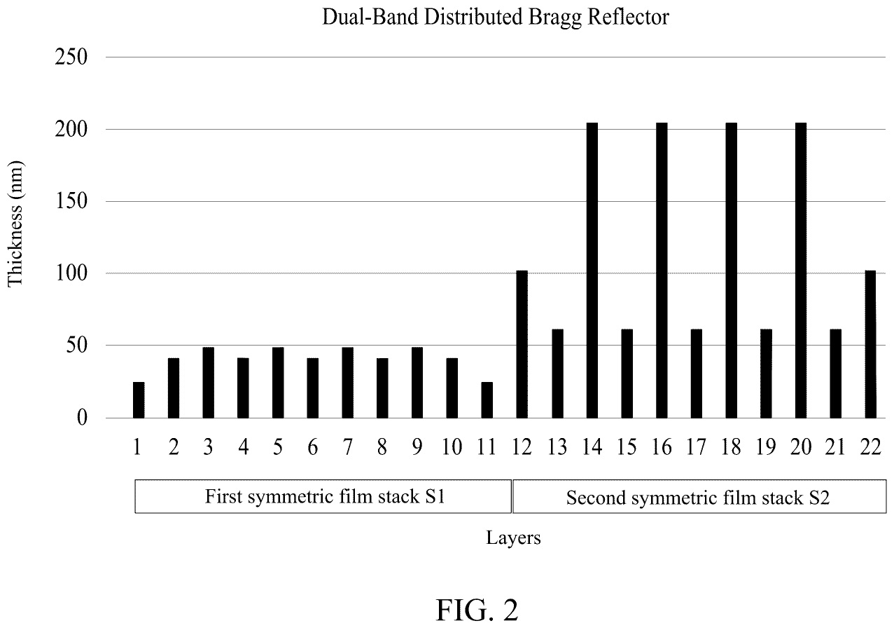

In particular, to enhance the reflection efficiency of the reflector, this invention arranges a first front-to-rear symmetric relationship in the first symmetric film stack S₁ and a second front-to-rear symmetric relationship in the second symmetric film stack S₂ of the distributed Bragg reflector structure 10. Please refer to FIG. 2, which illustrates a schematic diagram of the two front-to-rear symmetric relationships of the two symmetric film stacks in the distributed Bragg reflector structure of this invention. Specifically, taking the same embodiment as above as an example, the first front-to-rear symmetric relationship refers to the central layer L₆ of the first symmetric film stack S₁ as the center, where the thicknesses and oxide film materials of the layers before and after the central layer are identical. Referring to FIG. 1, FIG. 2, and Table 1 together, the 5th oxide film L₅ and the 7th oxide film L₇, located before and after the central layer L₆, have the same thickness of approximately 49.3 nanometers (nm) and are both made of titanium dioxide (TiO₂). Additionally, in the first symmetric film stack S₁, the 1st oxide film L₇ and the 11th oxide film L₁₁, located at the foremost and rearmost positions relative to the central layer L₆, have the same thickness of approximately 24.6 nanometers (nm) and are both made of titanium dioxide (TiO₂). Similarly, the second front-to-rear symmetric relationship refers to the central layer L₁₇ of the second symmetric film stack S₂ as the center, where the thicknesses and oxide film materials of the layers before and after the central layer are identical. For example, the 16th oxide film L₁₆ and the 18th oxide film L₁₈, located before and after the central layer L₁₇, have the same thickness of approximately 205.2 nanometers (nm) and are both made of silicon dioxide (SiO₂). Additionally, in the second symmetric film stack S₂, the 12th oxide film L₁₂ and the 22nd oxide film L₂₂, located at the foremost and rearmost positions relative to the central layer L₁₇, have the same thickness of approximately 102.6 nanometers (nm) and are both made of silicon dioxide (SiO₂).

In the specific embodiment described above, the thicknesses of the first oxide films and the second oxide films in the first symmetric film stack S₁ range from 20 to 60 nanometers (nm). On the other hand, the thicknesses of the first oxide films and the second oxide films in the second symmetric film stack S₂ range from 50 to 220 nanometers (nm). The total thickness of the distributed Bragg reflector structure 10 composed of these two symmetric film stacks ranges from 800 nanometers (nm) to 3 micrometers (μm).

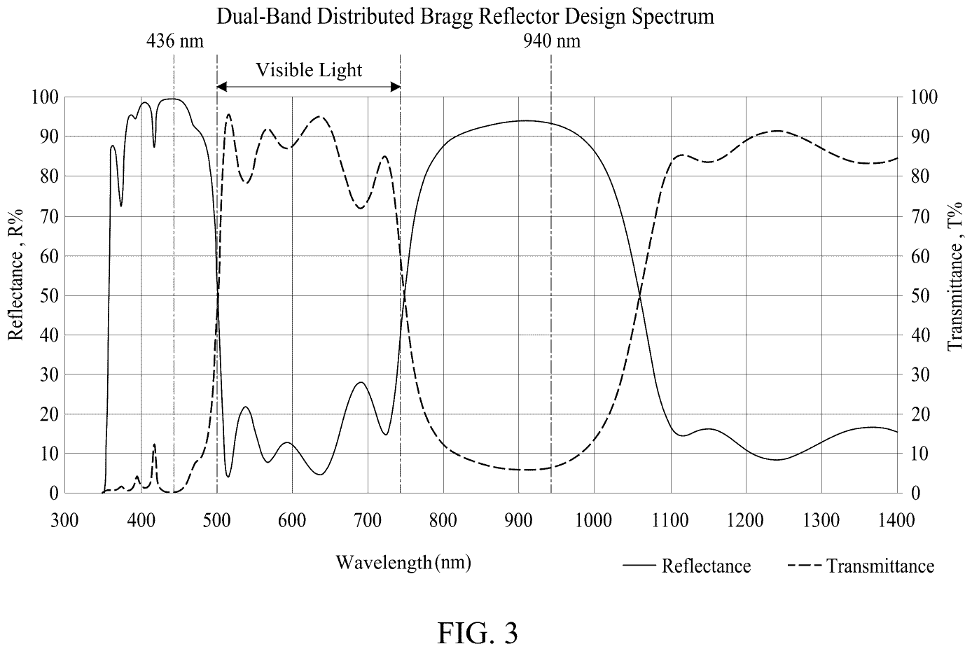

Furthermore, to achieve the dual-band reflection effect, preferably, the thicknesses of all 11 layers of the low-refractive-index oxide films and high-refractive-index oxide films in the second symmetric film stack S₂ are greater than those of the corresponding 11 layers in the first symmetric film stack S₁. Under this film structure, the design spectrum of the dual-band Bragg reflector structure of this invention exhibits the following characteristics: the first symmetric film stack S₁ achieves an optical reflectance greater than 80% at the 436 nm wavelength, with a full width at half maximum (FWHM) of 130 to 150 nm, suitable for ultraviolet wavelengths ranging from 370 to 500 nm. On the other hand, the second symmetric film stack S₂ achieves an optical reflectance greater than 80% at the 940 nm wavelength, with a FWHM of 200 to 400 nm, suitable for infrared wavelengths ranging from 750 to 1100 nm. Additionally, an average transmittance greater than 80% is achieved in the visible light region, suitable for wavelengths ranging from 500 to 750 nm, as shown in FIG. 3.

As described above, the dual-band Bragg reflector structure of this invention achieves high reflectance exceeding 80% for wavelengths outside the visible light range at 436 nm and 940 nm, while providing high average transmittance exceeding 80% for the visible light range of 500 to 750 nm. Consequently, the optical property of reflecting light outside the visible spectrum back into the substrate by the distributed Bragg reflector structure enables the use of 940 nm infrared light for edge-finding alignment of transparent substrates, overcoming the limitation of visible light in achieving edge alignment for transparent substrates. Additionally, at the 436 nm wavelength, it can be applied to the G-line exposure wavelength in subsequent photolithographic processes, enhancing the accuracy and intensity of exposure. On the other hand, in the visible light range, the dual-band Bragg reflector structure of this invention allows visible light to substantially pass through the transparent substrate and the reflector structure without causing reflection, thus avoiding interference with the calibration signal of alignment marks by visible light, and thereby enhancing the calibration signal strength of the alignment mark 32 on the surface of the wafer photoresist layer 30. Moreover, the reflector layers are made of dielectric oxide materials, which exhibit high-temperature resistance, capable of withstanding process temperatures up to 800 °C, ensuring the stability of the reflector structure during subsequent high-temperature film deposition processes, and thus improving process precision and efficiency. This heat resistance is particularly distinct from reflectors made of metal materials such as silver or aluminum, which have low melting points and are unsuitable for subsequent high-temperature processes. As such, the technology of this invention, with its high-temperature resistance and high dual-band reflectance characteristics, achieves superior multi-wavelength optical alignment calibration effects.

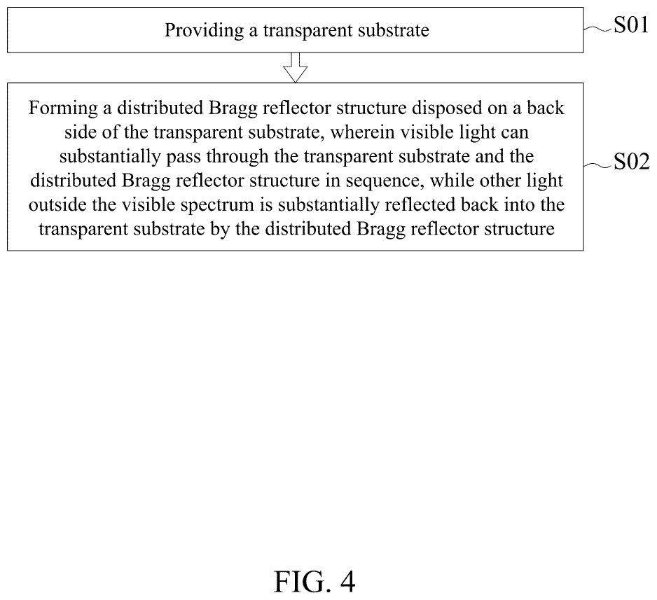

Please refer to FIG. 4, which illustrates a schematic diagram of the process steps for the semiconductor structure of this invention. First, in step S01, a transparent substrate is provided. Next, in step S02, a distributed Bragg reflector structure is formed, disposed on a back side of the transparent substrate, wherein the distributed Bragg reflector structure comprises: a first symmetric film stack having a plurality of pairs of a low-refractive-index oxide film and a high-refractive-index oxide film alternately stacked; and a second symmetric film stack having a plurality of pairs of the low-refractive-index oxide film and the high-refractive-index oxide film alternately stacked, wherein the thicknesses of the oxide films in the second symmetric film stack are greater than those in the first symmetric film stack, such that visible light can substantially pass through the transparent substrate and the distributed Bragg reflector structure in sequence, while other light outside the visible spectrum is substantially reflected back into the transparent substrate by the distributed Bragg reflector structure. The descriptions of the related components can be referred to the above content and will not be repeated here.

The above embodiments are provided to illustrate the implementations of the present invention and to explain its technical features, and are not intended to limit the scope of the present invention. Any modifications or equivalent arrangements that can be easily accomplished by those skilled in the art fall within the scope of the present invention, and the scope of the present invention should be defined by the claims.

What is claimed is:

1. A semiconductor structure, comprising:
a transparent substrate;
an epitaxial structure disposed on one side surface of the transparent substrate; and
a distributed Bragg reflector structure disposed on a back side of the transparent substrate opposite to the epitaxial structure,
wherein visible light can substantially pass through the epitaxial structure, the transparent substrate, and the distributed Bragg reflector structure in sequence, but other light outside the visible light can substantially be reflected back into the transparent substrate by the distributed Bragg reflector structure.

2. The semiconductor structure of claim 1, wherein the distributed Bragg reflector structure comprises a first symmetric film stack, the first symmetric film stack having a plurality of pairs of a first oxide film and a second oxide film alternately stacked, wherein a first refractive index of the first oxide film is greater than a second refractive index of the second oxide film.

3. The semiconductor structure of claim 2, wherein the thicknesses of each of the first oxide films and each of the second oxide films in the first symmetric film stack exhibit a first front-to-rear symmetric relationship.

4. The semiconductor structure of claim 2, wherein the distributed Bragg reflector structure further comprises a second symmetric film stack, the second symmetric film stack having a plurality of pairs of the first oxide film and the second oxide film alternately stacked, and the thicknesses of each of the first oxide films and each of the second oxide films in the second symmetric film stack are greater than the thicknesses of each of the first oxide films and each of the second oxide films in the first symmetric film stack.

5. The semiconductor structure of claim 4, wherein the thicknesses of each of the first oxide films and each of the second oxide films in the second symmetric film stack exhibit a second front-to-rear symmetric relationship.

6. The semiconductor structure of claim 2, wherein the first refractive index of the first oxide film and the second refractive index of the second oxide film range from 1.4 to 3.0.

7. The semiconductor structure of claim 2, wherein the first oxide film and the second oxide film are selected from the group consisting of silicon dioxide (SiO₂), titanium dioxide (TiO₂), tantalum pentoxide (Ta₂O₅), niobium pentoxide (Nb₂O₅), aluminum oxide (Al₂O₃), and zirconium dioxide (ZrO₂).

8. The semiconductor structure of claim 2, wherein the thicknesses of each of the first oxide films and the second oxide films in the first symmetric film stack range from 20 to 60 nanometers (nm).

9. The semiconductor structure of claim 4, wherein the thicknesses of each of the first oxide films and the second oxide films in the second symmetric film stack range from 50 to 220 nanometers (nm).

10. The semiconductor structure of claim 1, wherein a total thickness range of the distributed Bragg reflector structure is from 800 nanometers (nm) to 3 micrometers (μm).

11. The semiconductor structure of claim 1, wherein the other light comprises dual-band light at 436 nanometers (nm) and 940 nanometers (nm).

12. A semiconductor structure, comprising:
a transparent substrate; and
a distributed Bragg reflector structure disposed on a back side of the transparent substrate, comprising:
a first symmetric film stack disposed on the back side of the transparent substrate, the first symmetric film stack having a plurality of pairs of a low-refractive-index oxide film and a high-refractive-index oxide film alternately stacked; and
a second symmetric film stack having a plurality of pairs of the low-refractive-index oxide film and the high-refractive-index oxide film alternately stacked, wherein the thicknesses of each of the low-refractive-index oxide films and the high-refractive-index oxide films in the second symmetric film stack are greater than the thicknesses of each of the low-refractive-index oxide films and the high-refractive-index oxide films in the first symmetric film stack,
wherein visible light can substantially pass through the transparent substrate and the distributed Bragg reflector structure in sequence, but other light outside the visible light can substantially be reflected back into the transparent substrate by the distributed Bragg reflector structure.

13. The semiconductor structure of claim 12, wherein the thicknesses of each of the low-refractive-index oxide films and each of the high-refractive-index oxide films in the first symmetric film stack exhibit a first front-to-rear symmetric relationship, and the thicknesses of each of the low-refractive-index oxide films and each of the high-refractive-index oxide films in the second symmetric film stack exhibit a second front-to-rear symmetric relationship.

14. The semiconductor structure of claim 12, wherein refractive index of the low-refractive-index oxide film and the high-refractive-index oxide film range from 1.4 to 3.0.

15. The semiconductor structure of claim 12, wherein the low-refractive-index oxide film and the high-refractive-index oxide film are selected from the group consisting of silicon dioxide (SiO₂), titanium dioxide (TiO₂), tantalum pentoxide (Ta₂O₅), niobium pentoxide (Nb₂O₅), aluminum oxide (Al₂O₃), and zirconium dioxide (ZrO₂).

16. The semiconductor structure of claim 12, wherein the thicknesses of each of the low-refractive-index oxide films and the high-refractive-index oxide films in the first symmetric film stack range from 20 to 60 nanometers (nm).

17. The semiconductor structure of claim 12, wherein the thicknesses of each of the low-refractive-index oxide films and the high-refractive-index oxide films in the second symmetric film stack range from 50 to 220 nanometers (nm).

18. The semiconductor structure of claim 12, wherein a total thickness range of the distributed Bragg reflector structure is from 800 nanometers (nm) to 3 micrometers (μm).

19. The semiconductor structure of claim 12, wherein the other light comprises dual-band light at 436 nanometers (nm) and 940 nanometers (nm).

20. A manufacturing method for a semiconductor structure, comprising:
providing a transparent substrate; and
forming a distributed Bragg reflector structure disposed on a back side of the transparent substrate, the distributed Bragg reflector structure comprising:
a first symmetric film stack disposed on the back side of the transparent substrate, having a plurality of pairs of a low-refractive-index oxide film and a high-refractive-index oxide film alternately stacked; and
a second symmetric film stack having a plurality of pairs of the low-refractive-index oxide film and the high-refractive-index oxide film alternately stacked, wherein the thicknesses of each of the low-refractive-index oxide films and the high-refractive-index oxide films in the second symmetric film stack are greater than the thicknesses of each of the low-refractive-index oxide films and the high-refractive-index oxide films in the first symmetric film stack,
wherein visible light can substantially pass through the transparent substrate and the distributed Bragg reflector structure in sequence, but other light outside the visible light can substantially be reflected back into the transparent substrate by the distributed Bragg reflector structure.
